(19) United States
(12) Patent Application Publication
(10) Pub. No.: US 2005/0110478 A1
(43) Pub. Date: May 26, 2005

(54) Method and apparatus for detecting electrostatic charges during semiconductor fabrication process

(76) Inventor: Peng-Cheng Shi, Hsinchu (TW)

Correspondence Address: JIANQ CHYUN;INTELLECTUAL PROPERTY OFFICE, 7F-1, NO. 100, ROOSEVELT RD., SEC. 2, TAIPEI 100, TW

(21) Appl. No.: 10/719,593

(22) Filed: Nov. 21, 2003

(51) Int. Cl. G01R 19/00

(52) U.S. Cl. 324/76.11

(57) ABSTRACT

A process for detecting electrostatic charges on a wafer surface during the fabrication of semiconductor devices after the wafer is subject to a de-ionized water rinsing step to remove particles and other impurities from a wafer surface. This process includes the steps of: (a) positioning an insulation layer above a wafer surface on which electrostatic charge densities are to be scanned; (b) using a movable probe to measure voltages at various locations at the insulating layer; (c) collecting the measured voltage distribution; and (d) examining the collected voltage distribution to identify areas on the wafer surface correspondingly to high electrostatic charge density. Because high precision and high resolution scanning can be made with this method, trouble-shooting diagnosis to be expeditiously performed with minimum interruptions to the semiconductor fabrication operation.

### FIELD OF THE INVENTION

The present invention relates to a method which can be very used to detect electrostatic charges following a de-ionized water rinsing step during the fabrication of semiconductor devices to remove particles and other impurities from a wafer surface. More specifically, the present invention relates to a novel method, and an apparatus for carrying out the same, for use in the semiconductor industry, to conveniently and cost-effectively detect electrostatic charges that may be present on the surface of a semiconductor wafer following a rinsing step which uses pure water or de-ionized water, to remove particles, and/or other impurities. One of the most distinct advantages of the method of the present invention is that, because of its precision and high resolution, it can very quickly and accurately identify the troubled spot so as to allow a trouble-shooting diagnosis to be expeditiously performed. Another main advantage of the present invention is that, because of the relatively simple procedure involved, it can be very cost-effectively implemented which will cause only minimum interruptions of the fabrication operation.

### BACKGROUND OF THE INVENTION

Rinsing is a very important step in semiconductor fabrication processes. Typically, the rinsing step is performed using ultra high quality pure water or de-ionized water. Conventionally, the effectiveness of a rinsing process is measured by detecting the presence of particles or surface impurities, or by forming a metal-oxide semiconductor (MOS) device on the original oxide layer to qualitatively measure the stress-resistance thereof.

If the rinsing water contains particles or other impurities, these foreign substances of course will be carried onto the wafer surface, causing damages of the wafer and resulting in yield problems. More recently, it was discovered by the inventor of the present invention that, even with ultra-pure de-ionized rinsing water, undesirable problems can also be created. More specifically, it was discovered by the inventor of the present invention that if abnormalities are present in the rinsing water delivery system, the friction between water and the water delivery system, which is typically made of dielectric materials with high electric and corrosional resistances such as PFA, PTFE, etc, can cause electrostatic charges to be generated. These electrostatic charges will be carried by the rinsing water onto the wafer surface. When the electrostatic charges accumulate to a certain level, they can cause a dielectric layer, on which the electrostatic charges accumulate, to rupture. This phenomenon is called “charge damage”. An operation that cause electrostatic charges to be penetrate into the dielectric layer is called a charge damage.

As there exists the ever-present demand on semiconductor manufacturers to continuously reduce the physical dimensions of semiconductor devices, the resistance against charge damages that can be expected from a semiconductor device also continues to decline. As a result, it becomes increasingly critical during semiconductor fabricating processes to be able to quickly detect the presence of electrostatic charges, perform a trouble-shooting diagnosis, and have the problems solved and process resumed, without causing interruptions in the fabricating process. In addition to the charges that can be carried by the rinsing water, electrostatic charge damages can also be caused by the laminar air flow in the clean room, physical touches by human bodies, high-energy ion plantations, etc. As the semiconductor manufacturers are under an enormous pressure to cut cost by improving process yields, it is equally important to be able to timely and inexpensively detect those electrostatic charges so as to assure a smooth operation of the fabrication process.

FIG. 1 is a flowchart diagram which shows the main steps of a conventional process for detecting the charges on a wafer surface. It requires, among other things, the steps of: (1) wet cleaning and forming a sacrificial oxide layer; (2) removing the sacrificial oxide layer; (3) forming a gate layer first by oxidation; (4) deposition of poly or metal on the gate layer; (5) defining the gate pattern; (6) poly or metal etching to form the gate layer; (7) damage annealing; (8) running a charge damage process; (9) gate break-down probe; and (10) discard wafers that show high charge damages. As it can be seen from FIG. 1 and the above discussion, the conventional process for detecting the charges on a wafer surface is time- and labor-consuming, and it causes interruptions in the production processes.

### SUMMARY OF THE INVENTION

The primary object of the present invention is to develop an improved method which can be used to, cost-effectively and with only minimum process interruption, detect electrostatic charges following a de-ionized water rinsing step during the fabrication of semiconductor devices to remove particles and other impurities from a wafer surface. More specifically, the primary of the present invention is to develop an improved method, and an apparatus for carrying out the same, for use in the semiconductor industry, to cost-effectively and expeditiously detect electrostatic charges that may have accumulated on the surface of a semiconductor wafer following a rinsing step which uses pure water or de-ionized water, to remove particles, and/or other impurities. The method of the present invention allows high precision and high resolution scanning to be made, so that it can very quickly and accurately pinpoint the trouble spot and allow a trouble-shooting diagnosis to be expeditiously performed. Furthermore, the present invention involves a much simpler procedure than any of those in the prior art processes, and, as a result, it can be very cost-effectively implemented and will not cause major interruptions in the semiconductor fabrication operation.

The method disclosed in the present invention comprises the following main steps:
(a) Disposing a capacitor plate above a wafer surface on which electrostatic charges are to be measured on a local basis;
(b) Using a movable probe to measure voltages at various locations at the capacitor plate;
(c) Collecting the measured voltage distribution at the capacitor plate; and
(d) Determining area or areas on the wafer surface with correspondingly high electrostatic charge density.

When used in a semiconductor device fabrication process, the entire process begins with the wafer start, followed by gate oxidation, run charge damage process, then finally the wafer surface voltage scanning process described above. Finally, the gate oxide layer is removed and the wafer is re-used for further fabrication steps.

Although the method disclosed in the present invention is most advantageous for use in detecting abnormal electrostatic charges after the semiconductor wafer has been subject to a water rinsing step, it can also be used to provide the same function in situations where no water rinsing is involved.

### BRIEF DESCRIPTION OF THE DRAWING

The present invention will be described in detail with reference to the drawing showing the preferred embodiment of the present invention, wherein:

FIG. 1 is a schematic flowchart diagram showing the main steps of a conventional process for detecting electrostatic charges on a wafer surface.

FIG. 2 shows a schematic drawing of the first preferred embodiment of the apparatus for carrying out the method disclosed in the present invention to detect electrostatic charges on a wafer surface.

FIG. 3 is a schematic flowchart diagram showing the main steps of including the method of the present invention in a semiconductor device fabrication process.

FIG. 4A shows results obtained from a trouble-shooting test utilizing the method of the present invention, by measuring the voltage distribution over the surface of a just-fabricated wafer, to solve a yield problem which was traced to a faulty nozzle.

FIG. 4B shows that the number of bit fails prior to the trouble-shooting procedure.

FIG. 4C shows that the number of bit fails after the trouble-shooting procedure; it shows that the number of bit fails was substantially reduced after the original problem was diagonalized and solved using the method of the present invention.

FIG. 5 shows the design of a sectionalized capacitor plate used in the second preferred embodiment of the apparatus for carrying out the method of the present invention to detect electrostatic charges on a wafer surface.

FIG. 6 shows a third preferred embodiment of the apparatus for carrying out the method of the present invention to detect electrostatic charges on a wafer surface, wherein the capacitor plate has a small area which moves with the probe.

### DETAILED DESCRIPTION OF THE PREFERRED EMBODIMENT

The present invention discloses a novel and improved method for use in the semiconductor industry to measure the two-dimensional distribution of electrostatic charge densities on a wafer surface following a de-ionized water rinsing step during the fabrication of semiconductor devices to remove particles and other impurities from a wafer surface. The method of the present invention allows high precision and high resolution scanning of the electrostatic charge density distribution to be made, so that it can very quickly and accurately pinpoint the trouble spot and allow a trouble-shooting diagnosis to be expeditiously performed. While the method disclosed in the present invention is most advantageous for use in detecting abnormal electrostatic charge accumulations after the water rinsing step, it can also be used to provide the same function in situations where no water rinsing is involved. The present invention involves a much simpler procedure than any of those in the prior art processes, and, as a result, it can be very cost-effectively implemented and will not cause major interruptions in the semiconductor fabrication operation.

The method disclosed in the present invention comprises the following main steps:
(a) Disposing a capacitor plate above a wafer surface on which electrostatic charges are to be measured on a local basis;
(b) Using a movable probe to measure voltages at various locations at the capacitor plate;
(c) Collecting the measured voltage distribution at the capacitor plate; and
(d) Determining area or areas on the wafer surface with correspondingly high electrostatic charge density.

When used in a semiconductor device fabrication process, the entire process begins with the wafer start step, followed by gate oxidation step, and the step of running charge damage process, then the wafer surface voltage measuring process described above. Finally, the gate oxide layer is removed and the wafer is re-used for further fabrication steps.

The present invention will now be described more specifically with reference to the following examples. It is to be noted that the following descriptions of examples, including the preferred embodiment of this invention, are presented herein for purposes of illustration and description, and are not intended to be exhaustive or to limit the invention to the precise form disclosed.

### EXAMPLE 1

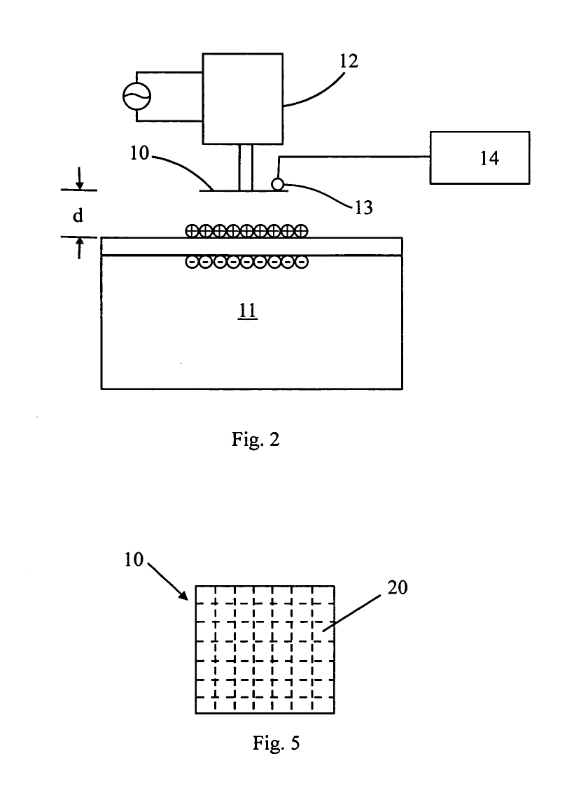

FIG. 2 shows a first preferred embodiment of the apparatus for carrying out the method of the present invention to detect electrostatic charges on a wafer surface.

In FIG. 2, it is shown a capacitor plate 10 which is positioned above a wafer surface 11 on which a two-dimensional distribution of electrostatic charges is to be measured. The capacitor plate 10 is controlled by a mechanical vibrator 12, which causes the wafer 11 to move vertically as well as horizontally. A movable probe 13, which is connected to a Kelvin probe electronics 14, is utilized to measure (i.e., scanning) voltages at various locations at the capacitor plate 10.

After the capacitor plate 10 is moved by the mechanical vibrator 12 to a predetermined horizontal above the wafer surface with a predetermined distance separating the two, the movable probe 13 begins to scan over the capacitor plate 10 to obtain a two-dimensional voltage distribution at the capacitor plate 10. The measured voltage ΔV, which is recorded with a recorder 14, is converted to localized electrostatic charge ΔQ according to the following equation:
ΔQ=ΔC×ΔV
where ΔC is calculated according the following formula:
ΔC=ε×ΔA/d
and ε is the dielectric constant of the space between the wafer surface and the capacitor plate 10, ΔA is the effective area covered by the probe 13, and d is the separation between the wafer surface and the capacitor plate 10.

After the voltage distribution is determined, the two-dimensional electrostatic density distribution on the wafer can be calculated.

### EXAMPLE 2

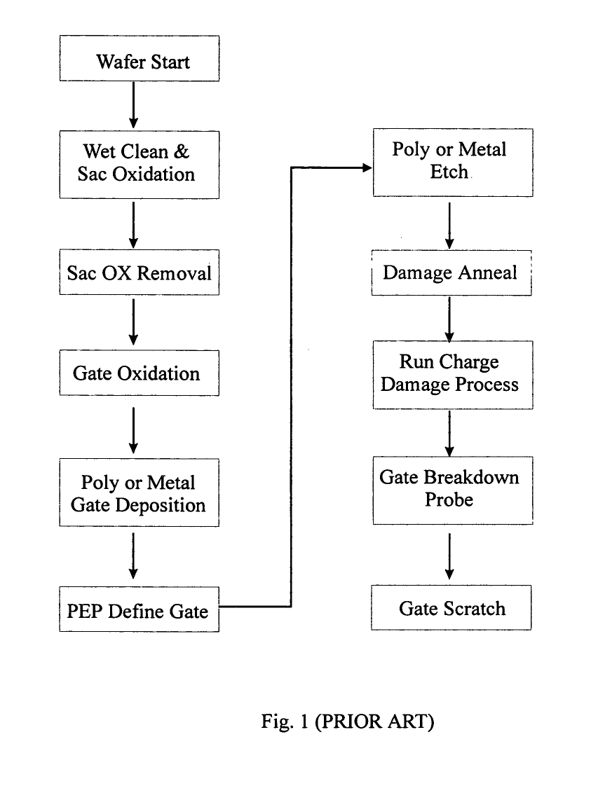

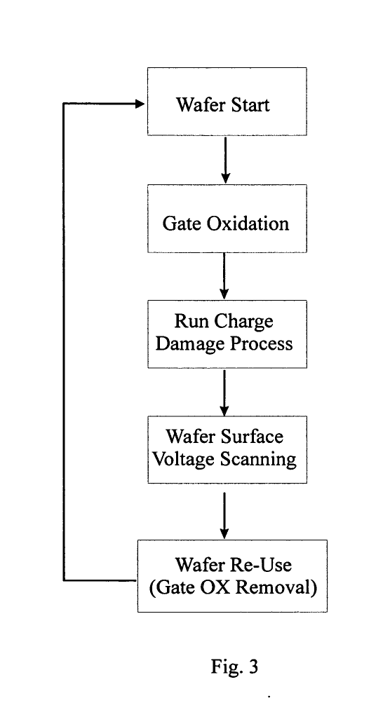

FIG. 3 is a schematic flowchart diagram showing the main steps of including the method of the present invention in a semiconductor device fabrication process. Compared to the conventional process as shown in FIG. 1, the method of the present invention is much more simplified. After an oxide layer is formed (Gate Oxidation), it is subject to a water rinsing step (Run Charge Damage Process). Thereafter, the steps described in Example 1 is performed (Wafer Surface Voltage Measurement). Since the method disclosed in the present invention does not require any additional physical contact with the wafer surface, the wafer fabrication process can be resumed without any interruption (Wafer Re-use, or Gate Oxide Removal).

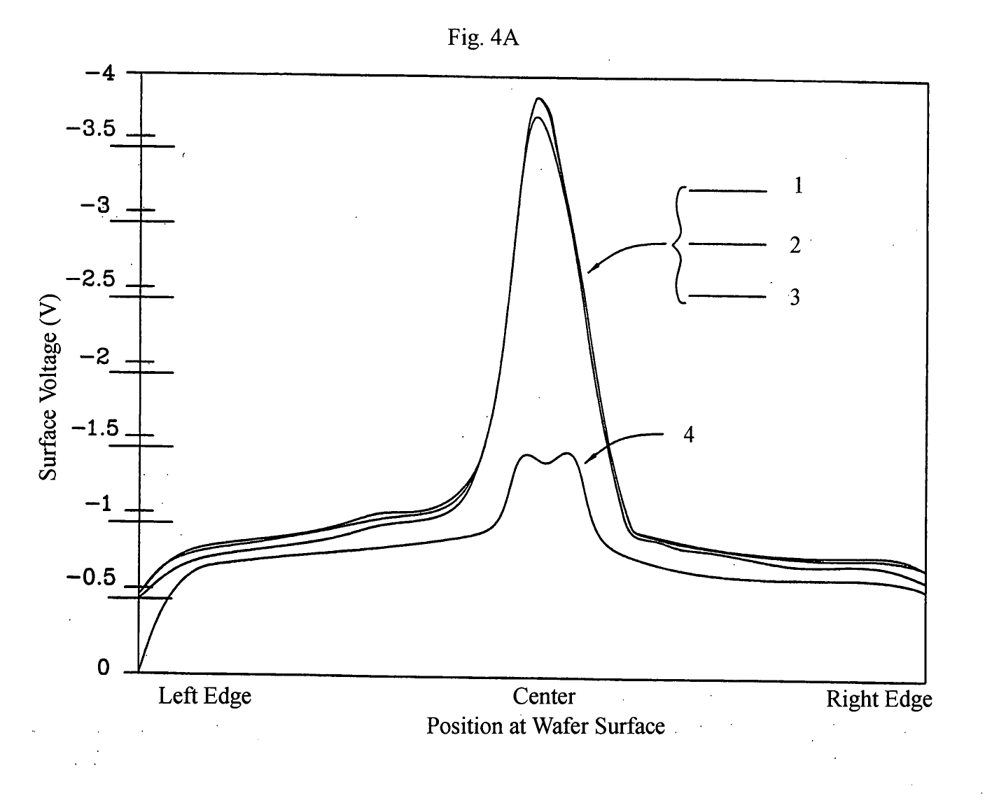

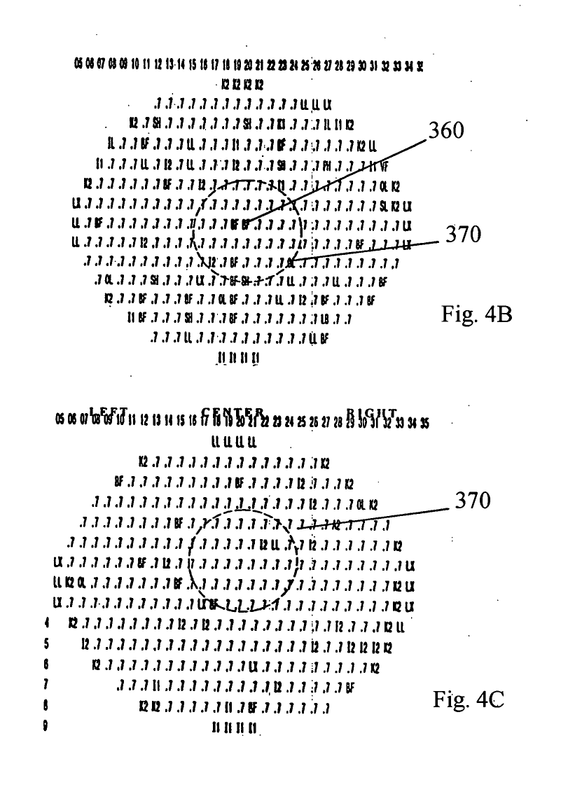

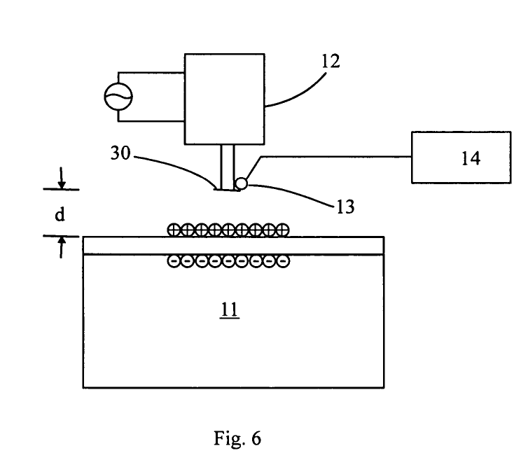

FIG. 4A shows results obtained from a trouble-shooting test utilizing the method of the present invention. Initially, the accumulation of electrostatic charges was thought to be due to inadequate pressure of the de-ionized water. However, as shown in FIG. 4, increasing the water pressure did not show any improvement. FIG. 4 shows that the pressure distribution curves obtained at nozzle pressures of 40 psi (curve 1), 50 psi (curve 2), and 60 psi (curve 3) are indiscriminate from each other. The simple and un-intrusive procedure of the method of the present invention allows the operator to try other options. One option was to adjust the nozzle rising angle and location. Results of this simple adjustment were shown in Curve 4. This immediately caused the electrostatic charge density to be substantially reduced. Further adjustment of the nozzle caused the problem to be eliminated. FIG. 4B shows that the histogram of bit fails, shown as 360, of a just-fabricated wafer prior to the implementation of the trouble-shooting procedure described in the present invention. FIG. 4C shows that the number of bit fails after the trouble-shooting procedure; it shows that the number of bit fails was substantially reduced after the original problem was diagonalized and solved using the method of the present invention. The effectiveness is particular profound in the center region of the wafer 370.

### EXAMPLE 3

In the second embodiment of the present invention, the apparatus is identical to that described in Example 1, except that the capacitor plate 10 is made of a plurality of isolated electrode sub-plates 20. This embodiment allows a better defined capacitor area to be employed for more quantitative results.

### EXAMPLE 4

In the third embodiment of the present invention, the apparatus is identical to that described in Example 1, except that the capacitor plate 30 has a very small area and it moves with the probe. This embodiment also allows a better defined capacitor area to be employed for more quantitative results.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. A method for detecting electrostatic charges on a wafer surface, comprising the steps of:
(a) disposing a capacitor plate above a wafer surface on which electrostatic charges are to be scanned;
(b) using a movable probe to measure voltages at various locations at the capacitor plate;
(c) collecting the measured voltage distribution; and
(d) examining the collected voltage distribution to identify areas on the wafer surface correspondingly to high electrostatic charge density.

2. The method for detecting electrostatic charges on a wafer surface according to claim 1, wherein the wafer contains a dielectric layer at its outmost surface.

3. The method for detecting electrostatic charges on a wafer surface according to claim 2, wherein the dielectric layer is an oxide layer.

4. The method for detecting electrostatic charges on a wafer surface according to claim 1, wherein the method is performed following a cleansing step using pure water or de-ionized water to remove particles or other impurities on the wafer surface.

5. The method for detecting electrostatic charges on a wafer surface according to claim 1, wherein the capacitor plate is structured such that it can be moved both vertically and horizontally above the wafer surface.

6. The method for detecting electrostatic charges on a wafer surface according to claim 1, wherein the capacitor plate is made of a plurality of capacitor sub-plates electrically insulated from each other.

7. A method for detecting electrostatic charges on a wafer surface, comprising the steps of:
(a) disposing a capacitor plate above a wafer surface on which electrostatic charges are to be scanned;
(b) attaching a probe on the capacitor plate;
(c) moving the capacitor plate horizontally above the wafer surface so as to allow the probe to measure voltages at various locations above the wafer surface;
(d) collecting the measured voltage distribution; and
(e) examining the collected voltage distribution to identify areas on the wafer surface correspondingly to high electrostatic charge density.

8. The method for detecting electrostatic charges on a wafer surface according to claim 7, wherein the wafer contains a dielectric layer at its outmost surface.

9. The method for detecting electrostatic charges on a wafer surface according to claim 8, wherein the dielectric layer is an oxide layer.

10. The method for detecting electrostatic charges on a wafer surface according to claim 7, wherein the method is performed following a cleansing step using pure water or de-ionized water to remove particles or other impurities on the wafer surface.

11. The method for detecting electrostatic charges on a wafer surface according to claim 7, wherein the capacitor plate is structured such that it can be moved both vertically and horizontally above the wafer surface.

12. An apparatus method for detecting electrostatic charges on a wafer surface, comprising the steps of:
(a) movable capacitor plate to be placed above a wafer surface on which electrostatic charges are to be scanned;
(b) a movable probe to measure voltages at various locations at the capacitor plate; and
(c) a recorder to collect and record the measured voltage distribution.

13. The apparatus for detecting electrostatic charges on a wafer surface according to claim 12, wherein the wafer contains a dielectric layer at its outmost surface.

14. The apparatus for detecting electrostatic charges on a wafer surface according to claim 13, wherein the dielectric layer is an oxide layer.

15. The apparatus for detecting electrostatic charges on a wafer surface according to claim 12, which is to be performed following a cleansing step using pure water or de-ionized water to remove particles or other impurities on the wafer surface.

16. The apparatus for detecting electrostatic charges on a wafer surface according to claim 12, wherein the capacitor plate is structured such that it can be moved both vertically and horizontally above the wafer surface.

17. The apparatus for detecting electrostatic charges on a wafer surface according to claim 12, wherein the capacitor plate is made of a plurality of capacitor sub-plates electrically insulated from each other.
